(19) United States
(12) Patent Application Publication
(10) Pub. No.: US 2026/0029441 A1
(43) Pub. Date: Jan. 29, 2026

(54) POWER VECTOR ANALYZER WITH TRACKING NULL AND TRACKING GATES FOR POWER GRID MONITORING

(71) Applicant: Tektronix, Inc., Beaverton, OR (US)

(72) Inventors: John J. Pickerd, Hillsboro, OR (US); Keith R. Tinsley, Eugene, OR (US)

(21) Appl. No.: 19/275,078

(22) Filed: Jul. 21, 2025

Related U.S. Application Data
(60) Provisional application No. 63/675,220, filed on Jul. 24, 2024.

(51) Int. Cl. G01R 19/00; G01R 13/02; G01R 19/25; G06F 16/22; G06F 16/28

(52) U.S. Cl. CPC G01R 19/0053; G01R 13/029; G01R 19/003; G01R 19/2513; G06F 16/2237; G06F 16/285

(57) ABSTRACT

A power monitoring system includes one or more power vector analyzers, and a power controller having one or more ports to receive transient event data comprising one or more power images and associated metadata for a transient event from the one or more power vector analyzers, and one or more processors configured to execute code to cause the one or more processors to convert the one or more power images from the one or more power vector analyzers and the associated metadata to one or more transient event vectors, and store the one or more transient event vectors in a vector database.

### CROSS-REFERENCE TO RELATED APPLICATIONS

This disclosure is a non-provisional of and claims benefit from U.S. Provisional Patent Application No. 63/675,220, “POWER VECTOR ANALYZER WITH TRACKING NULL AND TRACKING GATES FOR POWER GRID MONITORING,” filed Jul. 24, 2024, the disclosures of which is incorporated herein by reference in its entirety. This application is also related to U.S. patent application Ser. No. 18/914,685, “POWER VECTOR ANALYZER,” filed Oct. 14, 2024, the disclosures of which is incorporated herein by reference in its entirety.

### TECHNICAL FIELD

This disclosure relates to power grid monitoring, more particularly to test and measurement systems for power grid monitoring, and even more particularly to a power vector analyzer (PVA).

### BACKGROUND

U.S. patent application Ser. No. 18/914,685, filed Oct. 14, 2024, hereinafter “the '685 application,” the contents of which are hereby incorporated by reference into this application, discloses a Power Vector Analyzer (PVA) instrument, for analysis and monitoring of power on a line.

Typically, a unit referred to as Phase Measurement Unit (PMU) monitors the power grid. PMUs measure the voltage, current and frequency of electricity flowing through it. The PMU collects time-synchronized data and helps to detect and identify power grid disturbances, such as blackouts, voltage sags, and other power quality issues. PMUs are installed at various locations in the power grid to provide a comprehensive view of the system's health and enable real-time monitoring and control.

PMUs typically display a phasor diagram that represents a voltage vector and current vector phase angle for each of the three legs of a three-phase power location on the grid. The phasor diagrams, like 10 in FIG. 1, update continuously as the phase angles change due to reactive loads. Similarly, the voltage and current display on the right side shows the voltage for the three different phases as 12, 14, and 16. The area 18 in the current display shows a transient event. However, one cannot readily tell power direction of the transient, magnitude, the transient apparent power, nor how it is oscillating between inductive and capacitive reactance at a given instance.

### BRIEF DESCRIPTION OF THE DRAWINGS

FIG. 1 shows examples of diagrams displayed by a phasor measurement unit.

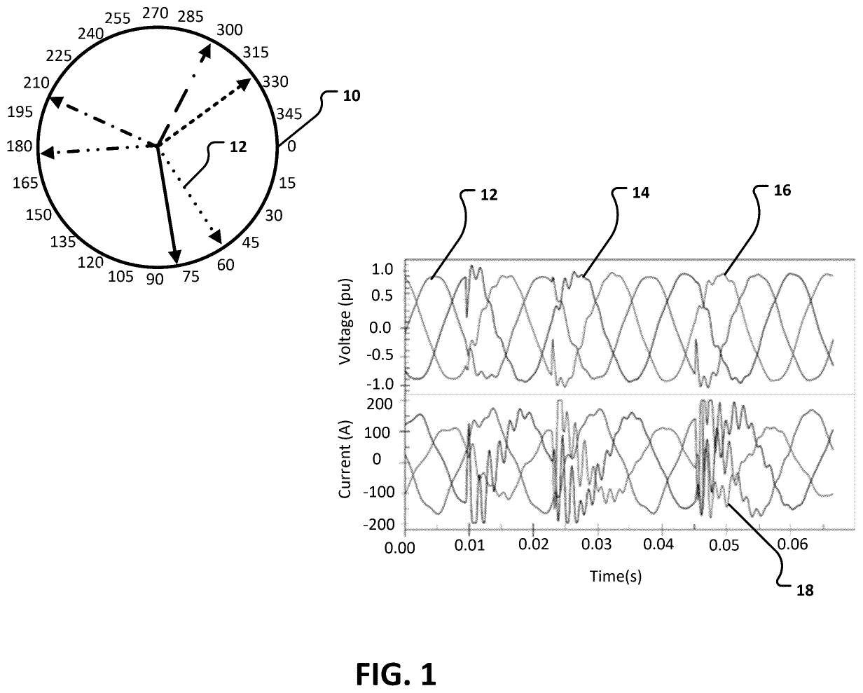

FIG. 2 shows an embodiment of a power grid employing power vector analyzers (PVAs).

FIG. 3 shows a system diagram of an embodiment of power control system including multiple PVAs distributed across a power grid, a tensor builder, and an artificial intelligence embedding with a vector database.

FIG. 4 shows an embodiment of a user interface on a power vector analyzer (PVA) displaying quiescent power for three-phase power.

FIG. 5 shows an embodiment of a user interface on a PVA during nulling of quiescent power.

FIG. 6 shows an embodiment of a user interface on a PVA displaying nulled quiescent power.

FIG. 7 shows an embodiment of a user interface on a PVA displaying measured power transients relative to a nulled quiescent power.

FIG. 8 shows an embodiment of a user interface on a PVA displaying tracking limit test circles for three phases of power.

FIG. 9 shows an embodiment of a user interface on a PVA displaying a small transient event crossing the limit circles and generating triggers.

FIG. 10 shows an embodiment of a user interface on a PVA displaying a transient event after application of a tracking null.

### DETAILED DESCRIPTION

The embodiments as disclosed herein provide a better view and understanding of characteristics of transient events on the power grid, such as complex dynamic bidirectional apparent power transients. The source of these events, referred to here as transient events, May comprise one of numerous examples including large induction power startups, sudden on of power from megawatt charging stations, downed power lines, exploding power transformers, a lightning strike, etc. The embodiments provide an image display that captures all aspects of the dynamic power transient variations of magnitude, phase angle, and direction of the power over the duration of the transient event.

The embodiments herein normalize and isolate the transient event by incorporating a novel tracking limit test circle and determining a tracking null normalization that removes the quiescent power from each PVA that sees the event at different GPS positions. This feature allows the system to ignore quiescent power that continuously varies at some slower rate than would be seen in a transient event. Quiescent power may be different at different times at different PVA locations. The power level at various monitoring points on the grid may change at different times at different points on the grid but not involve a transient event. The embodiments normalize, or null out, the quiescent power at each location normalized. This way each PVA location that sees the dynamic transient will see the transient as it changes or affects the PVA when the transient travels from the transient origin to different remote locations. This results in a multidimensional view of the event that potentially may be useful for locating the position of the event when aided by AI vector database of many types of past events and known information about those events.

The embodiments herein also create image and text arrays for the acquired transient event from each PVA that captured the event. The embodiments create a tensor representation of the image group to obtain a single AI embedding vector for the event data from all PVAs. Language will describe key characteristics of the event cause, location, or other info and will be associated with the event embedding. Over time, as the vector database grows, the AI system can classify new events that occur on the grid. The vector database may reside at the power distribution centers, the transient substations, control stations, etc., or may be distributed across the system with automatic updating between sites.

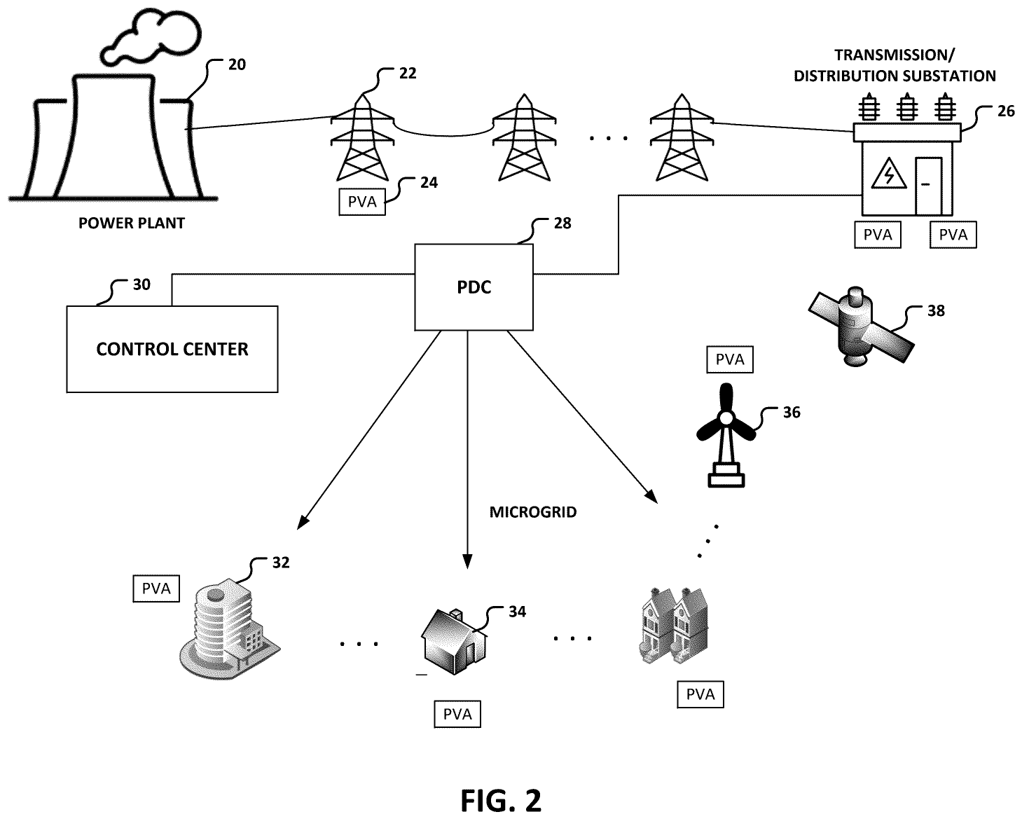

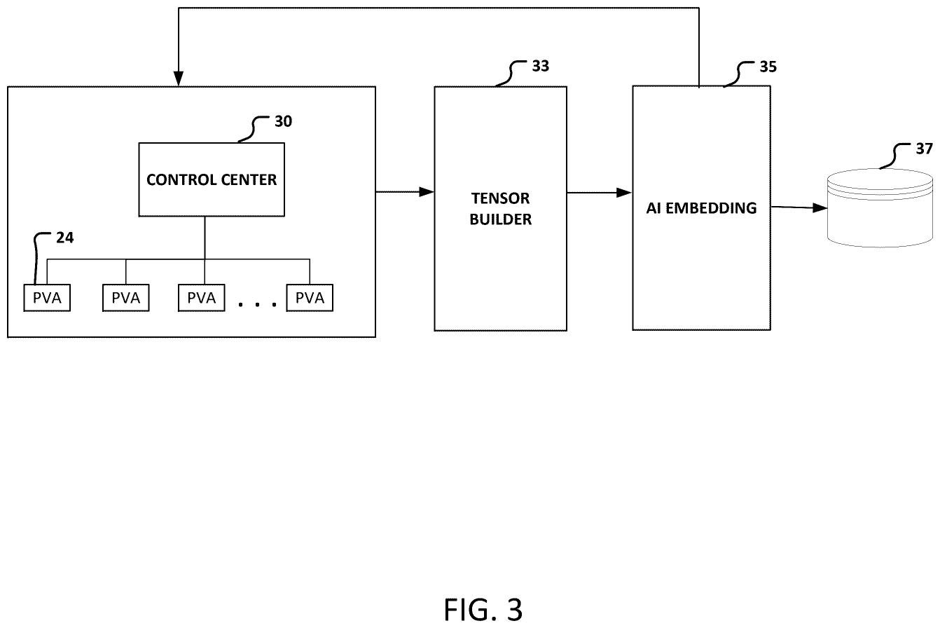

FIG. 2 shows an embodiment of a power grid that includes PVAs at strategic locations, in one embodiment identifiable by GPS coordinates using satellites such as 38. The PVAs may reside in more or fewer locations that those shown. The power grid may include, as examples, power generation plants like 20, power line towers like 22, power transmission and/or distribution substations like 26, alternative energy generation sites, like wind farm 36, solar farms, not shown, a power distribution center (PDC) like 28, and one or more control centers like 30. PVAs may reside at power consumption sites as well, including office and industrial buildings like 32, residential buildings like 34. The power grid may include large areas having multiple sub-grids or may comprise a sub-grid in the implementation of the embodiments. The PDC 28 and the control center 30 and all the PVAs in the grid will communicate by wireless, wired, or satellite communications. Each PVA may communicate only with the PDC and/or the control center or may communicate amongst themselves too. In one embodiment, the vector database 37, shown in FIG. 3, is aggregated with all the information from all of the PVAs. This can then be made available for power grid monitoring and formulating derivatives related to power grid enhancements, including, but not limited to prescribed Artificial Intelligence/Machine Learning (AI/ML) services. The AI/ML services may encompass predictive measures, including, but not limited to, predictive maintenance, load sharing/peak power distribution, and anomaly trend identification.

FIG. 3 shows a block diagram of how the PVAs and the control center can communicate transient events and the control center can classify them. As discussed regarding FIG. 2, multiple PVAs like 24 reside at different positions on the power grid. All PVAs communicate transient event data back to the control center 30. Each PVA may see the same event, providing a multidimensional view that can be unique to where it is located. As used herein, the term “power images” comprise the images communicated from the PVAs that show transient events. These images may include tracking limit test circles, discussed below, that assist in identifying the existence and in some respects the magnitude of the transient vents.

The tensor builder 33 has the task of taking the multiple PVA apparent power images and metadata and consolidating those into a single tensor space for creating a vector. The tensor building process comprises part of the vector building process and may involve placing the images from data base into a movie and consolidating the movie into a single vector by passing it through an AI embedding model 35 and its transformers. Alternatively, each image and text may pass through an AI model such as CLIP (Contrastive Language-Image Pre-training), as an example, to create a vector for the image and text in the vector data base 37. If the process creates a vector for each power image from each PVA, the multiple vectors for a single event must be combined such as by pooling or averaging for comparison. The end result is that the AI embedding is configured and if necessary pretrained once such that new data can continuously be added and distinguished without the need for retraining as the grid characteristics may change over time. New transient events will be formed into a tensor and then embedded into a vector. Then this vector will be matched against the vectors stored in the database in order to classify the characteristics of the event. If no match exists, the system will notify an operator who will then provide a classification for the vector to be stored in the database.

As discussed above, the vector database may also include vectors related to monitoring of the power grid during operations that do not involve a transient event. The control center may collect information from the PVAs periodically or during certain events other than transient events, such as during peak power usages, high load events, etc. The ML system may create vectors for these events with solutions such as load sharing, power distribution changes, etc. When conditions exist during normal operations that require a response, the ML system may provide services to better manage the power distribution.

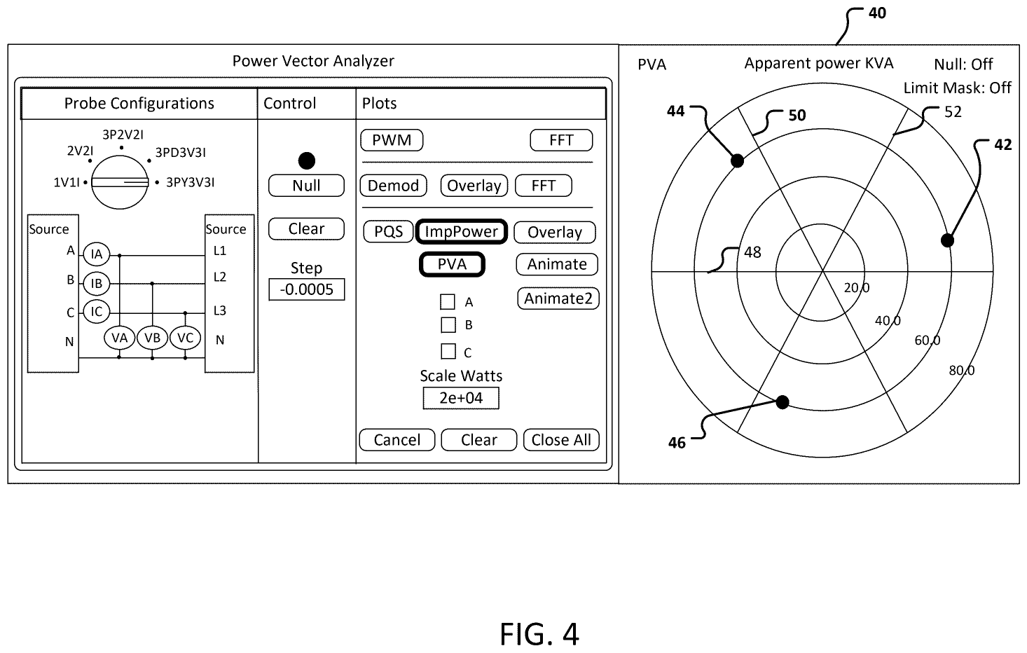

FIG. 4 shows an embodiment of a PVA. PVA of the embodiments can display the quiescent power signals on power lines in the grid. FIG. 4 shows a user interface 40 having controls on the left side and the user interface 40 on the right. The dots 42, 44, and 46, represent the “reference” apparent power signal for each of three phases on a polar grid, each phase being 120° out of phase with the other two phases. Lines 48, 50 and 52 and points on their axes have zero phase between the voltage and current. Points “above” the lines have inductive reactance, and “below” the line have the capacitive reactance. Lines 50 and 52 are 120 degrees out of phase from line 48 and each other to represent the different phase on the power lines. The term “reference apparent power” applies to the apparent power being displayed before removal of the quiescent power to differentiate them from the apparent power being measured after the null process.

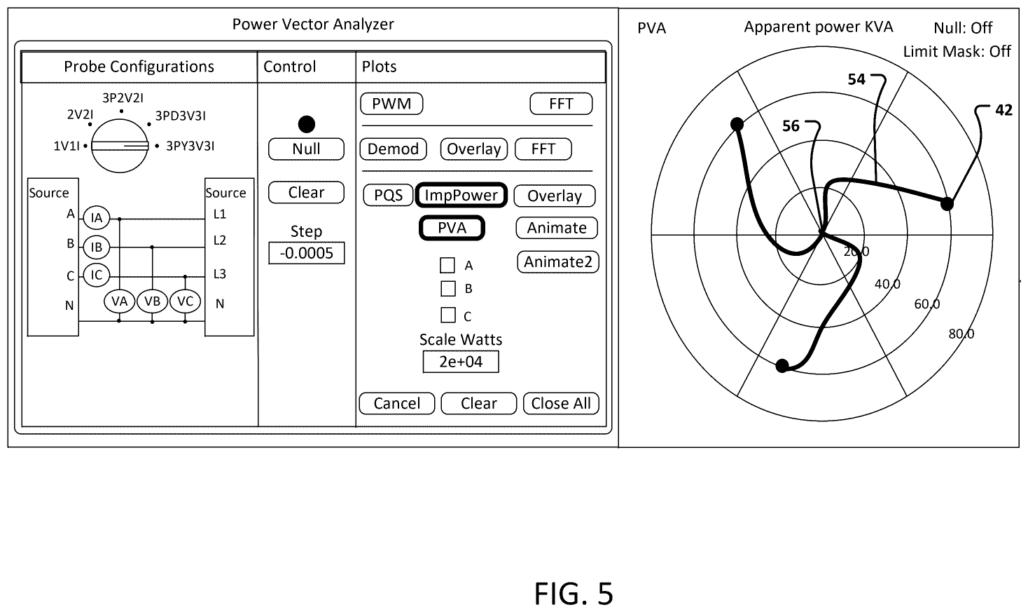

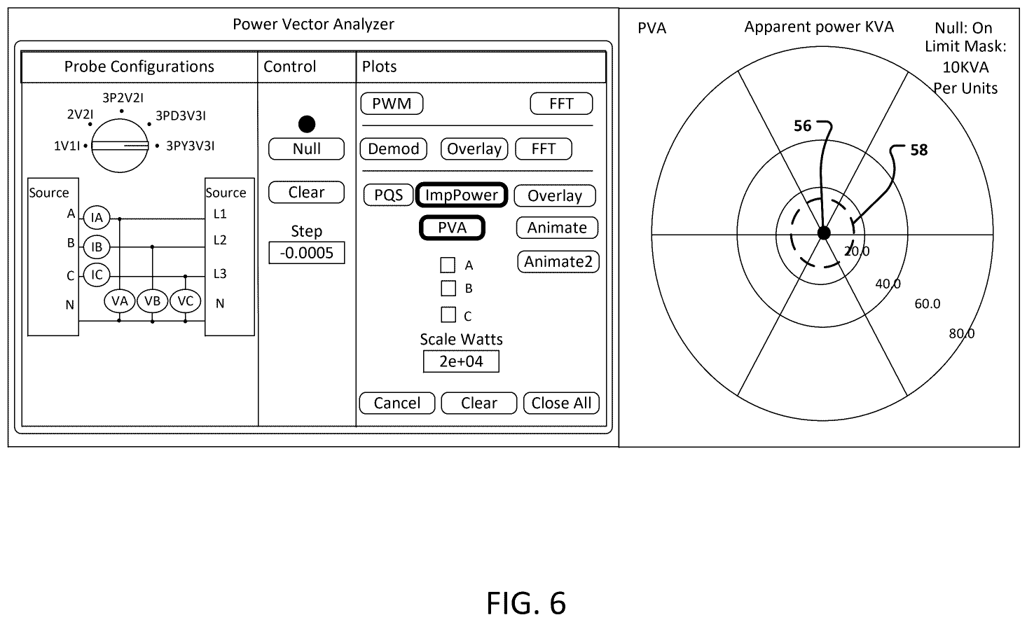

FIG. 5 shows an embodiment of the user interface during the null calculation process that will be discussed in detail below. The null process essentially removes quiescent power from the apparent power measurements, allowing more accurate presentation and measurement of transient power fluctuations. This process may involve using a quadrature synchronous detector (QSD) such as those discussed in detail in the '685 application, incorporated by references in its entirety above. A QSD or other similar device generates a null vector that “zeroes out” the quiescent power to then only display the apparent power. The lines such as 54 between each dot such as 42 and the center of the chart 56 represent the process of determining the null vector that the system adds to the reference apparent power to remove quiescent power from future measurements. FIG. 6 shows the resulting display where all three dots have moved to center 56, indicating that the quiescent power has been nulled and the apparent power appears to be zero for all three phases.

FIG. 6 also shows a limit circle, 58. The limit circuit allows the user, or the control center, to set a limit mask. This sets the limit of apparent power measurements as to how far “away” or above the null centers can get before causing a reaction in the PVA. By applying the null, the quiescent power from each line has been “removed” from the display, allowing for better detection of transient events.

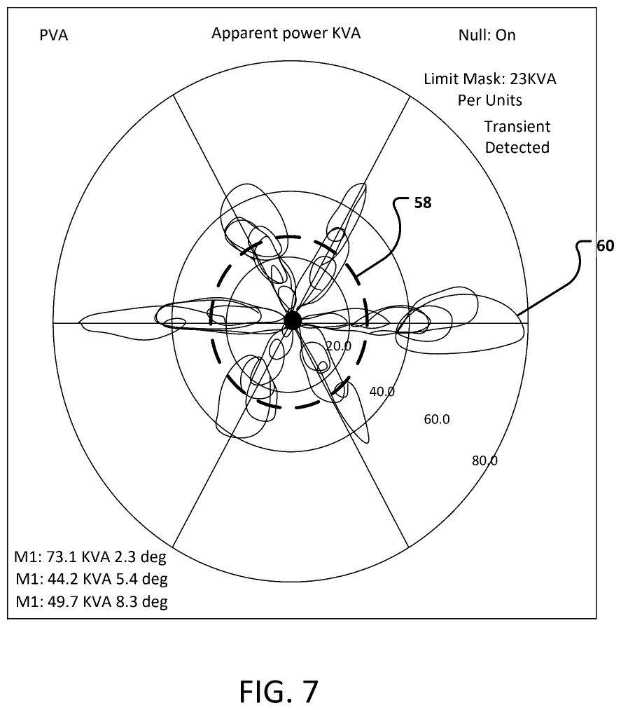

FIG. 7 shows transient apparent power fluctuations relative to the null center, with transients shown for each phase of power, such as 60 for one phase. One or more of the lines has a power level that exceeds the limit mask. When the apparent power transient signals exceed the limit mask 58, this causes the PVA to send the power image of the transient event and its associated metadata to the control center, in one embodiment. The user interface presents a message “Transient Detected.” One should note that the power image being sent to the control center comprises a likely scenario. The control center would receive power images from several PVAs, which would then allow the control center to develop a view of the transient event geographically, as the PVAs at different locations may have different data based upon the location of the PVAs.

It is possible that the PVA itself may act as a local node in the AI network and can detect the transient, create the vector, search a local copy of the vector database, and receive the classification of the event. It would then communicate the classification to other local nodes, including the control center, and all the local nodes could update their local copies of the vector database.

The above figures show the events with a “fixed” null. The null does not change with the quiescent power at the PVA location in the grid. The embodiments here employ a “tracking” null so that transient events can be isolated from quiescent power. This requires the use of a “tracking” limit circle.

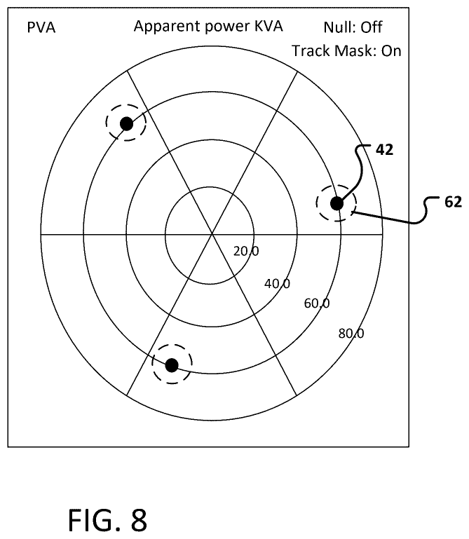

In the above figures, the limit circle does not track with the center of the quiescent power. As mentioned above, the user may define a limit circle to test against the plotted power signals to determine a dynamic transient event. If the system is not tracking nulled, three limit circles will exist, one for each phase of power as shown in FIG. 8, such as the tracking limit circle 62 for point 42. The tracking null can be defined separately for each of the three tracking limit circles, which form the tracking limit masks. The quiescent power in each is the center point of the mask circle.

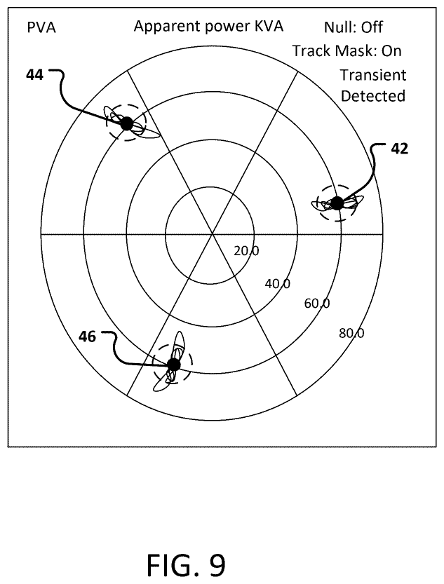

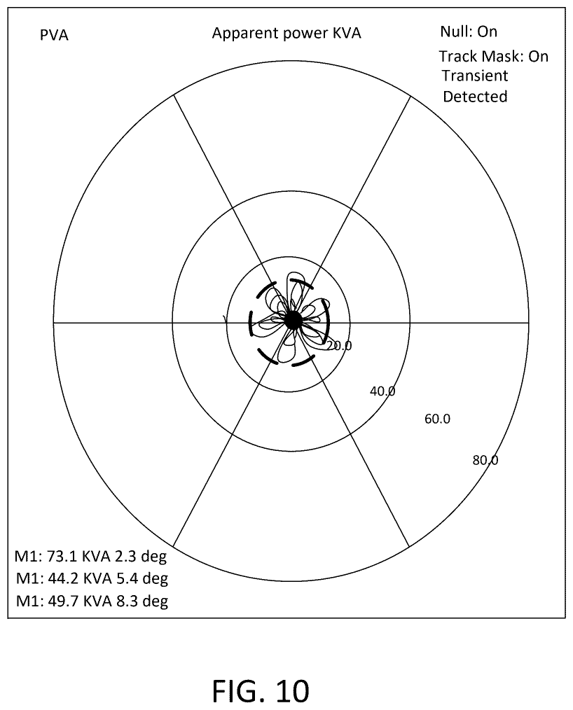

FIG. 9 shows the display after a small transient event has occurred on the power lines. In the embodiment here, the tracking limit mask was exceeded in all three phases. The transient event that triggers the report to the central controller could occur on only one of the phases. To obtain the power image, quiescent power in each circle is subtracted from the total event. In this view all three limit mask circles move to the center of the vector display. Now the power for the transient event is displayed as the deviation away from the quiescent power, as shown in FIG. 10.

PVAs with tracking null and tracking gates for power grid monitoring, according to embodiments of the disclosure, represent a significant leap forward in the domain of electrical grid management and analysis. Embodiments of the disclosure encapsulate a novel approach to the monitoring of complex dynamic transient events across power grids, employing a sophisticated mechanism of tracking gate limit test circles and tracking null normalization. Embodiments of the disclosure capture triggered transient power events from multiple PVAs that observe the event and submit the data to an AI embedding system for classification of the important characteristics of the event. The PVA's innovative design and functionality underscore a significant advancement for modernizing and enhancing power grid analysis and maintenance.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried out by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a power monitoring system, comprising: one or more power vector analyzers; and a power controller, comprising: one or more ports to receive transient event data comprising one or more power images and associated metadata for a transient event from the one or more power vector analyzers; and one or more processors configured to execute code to cause the one or more processors to: convert the one or more power images from the one or more power vector analyzers and the associated metadata to one or more transient event vectors; and store the one or more transient event vectors in a vector database.

Example 2 is the power monitoring system of Example 1, wherein the one or more processors are further configured to execute code to cause the one or more processors to: search the vector database for vectors that match one of the one or more transient event vectors; when a match is found, use a classification from the match to classify the transient event; and when a match is not found, add the vector to the vector database.

Example 3 is the power monitoring system of either of Examples 1 or 2, wherein the code that causes the one or more processors to convert the one or more power images and associated metadata to one or more transient event vectors comprises code that causes the one or more processors to create a transient event vector for each power image and associated metadata.

Example 4 is the power monitoring system of Example 3, wherein the one or more processors are further configured to execute code to cause the one or more processors to: combine the transient event vectors for each power image related to the transient event by one of averaging or pooling the transient event vectors to create a combined transient event vector; and using the combined transient event vector to search the vector database.

Example 5 is the power monitoring system of any of Examples 1 through 4, wherein the code that causes the one or more processors to convert the one or more power images and associated metadata to one or more transient event vectors comprises code that causes the one or more processors to place each of the one or more power images received into an image sequence and consolidating the image sequence into one transient event vector.

Example 6 is the power monitoring system of any of Examples 1 through 5, wherein the power controller resides at a central location and the one or more power vector analyzers are distributed across a power grid.

Example 7 is the power monitoring system of any of Examples 1 through 6, wherein each of the one or more power vector analyzers are distributed across a power grid and each power vector analyzer contains the power controller, and the one or more power vector analyzers communicate with others of the one or more power vector analyzers to update the vector database at each power vector analyzer.

Example 8 is the power monitoring system of any of Examples 1 through 7, wherein each power vector analyzer further comprises one or more processors configured to execute code to cause the one or more processors to define a limit mask for each phase of power being displayed on a display of the power vector analyzer.

Example 9 is the power monitoring system of Example 8, wherein the one or more processors are further configured to execute code that causes the one or more processors to: receive a signal indicating that the power vector analyzer is to null quiescent power for each phase of power being displayed on the display of the power vector analyzer; and display apparent power for each phase of power.

Example 10 is the power monitoring system of Example 9, wherein the one or more processors are further configured to: determine that a transient event has occurred because power in one or more of phases exceeded a tracking mask limit for that phase; subtract the quiescent power of each phase of power from a total event power; and display an image of power for the transient event at a center of the display with the transient event being displayed as a deviation from the quiescent power, the image of the transient event becoming one of the one or more the power images.

Example 11 is the power monitoring system of any of Examples 1 through 10, wherein the vector database resides in a centralized location and the one or more processors are further configured to execute code that causes the one or more processors to: monitor power grid operations; and provide one or more of artificial intelligence and machine learning services that include at least one of predictive measures, predictive maintenance, load sharing, peak power distribution and anomaly trend identification, based upon the monitoring.

Example 12 is a method of monitoring power in a grid, comprising: receiving one or more power images with associated metadata for a transient event in at least one phase of three phases of power from one or more power vector analyzers; converting the power images from the one or more power vector analyzers and the associated metadata to one or more transient event vectors; and store the one or more transient event vectors in a vector database.

Example 13 is the method of Example 12, further comprising: searching the vector database for vectors that match one of the one or more transient event vectors; and when a match is found, use a classification from the match to classify the transient event.

Example 14 is the method of either of Examples 12 or 13, wherein converting the one or more power images and associated metadata to one or more transient event vectors comprises creating a transient event vector for each power image and associated metadata.

Example 15 is the method of Example 14, wherein converting the one or more power images and associated metadata to one or more transient event vectors comprises: combining the transient event vectors for each power image related to the transient event by one of averaging or pooling the transient event vectors to create a combined transient event vector; and using the combined transient event vector to search the vector database.

Example 16 is the method of any of Examples 12 through 15, wherein converting the one or more power images and associated metadata to one or more transient event vectors comprises placing each of the one or more power images received into an image sequence and consolidating the image sequence into one transient event vector.

Example 17 is the method of any of Examples 12 through 16, further comprising: receiving a signal at the one or more power vector analyzers indicating that the one or more power vector analyzers are to null quiescent power for each of phase of power being displayed on a user interface of one of the one or more the power vector analyzers; and displaying apparent power for each phase of power.

Example 18 is the method of Example 17, further comprising: determining that a transient event has occurred because power in one or more phases exceeded a tracking mask limit for that phase; subtracting quiescent power of each phase from a total event power; and displaying an image of power for the transient event at a center of the display with the transient event being displayed as a deviation from the quiescent power, the image of the transient event becoming one of the one or more power images.

Example 19 is the method of any of Examples 12 through 18, further comprising: monitoring power grid operations; and providing one or more of artificial intelligence and machine learning services that include at least one of predictive measures, predictive maintenance, load sharing, peak power distribution and anomaly trend identification, based upon the monitoring.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

1. A power monitoring system, comprising:
one or more power vector analyzers; and
a power controller, comprising:
one or more ports to receive transient event data comprising one or more power images and associated metadata for a transient event from the one or more power vector analyzers; and
one or more processors configured to execute code to cause the one or more processors to:
convert the one or more power images from the one or more power vector analyzers and the associated metadata to one or more transient event vectors; and
store the one or more transient event vectors in a vector database.

2. The power monitoring system as claimed in claim 1, wherein the one or more processors are further configured to execute code to cause the one or more processors to:
search the vector database for vectors that match one of the one or more transient event vectors;
when a match is found, use a classification from the match to classify the transient event; and
when a match is not found, add the vector to the vector database.

3. The power monitoring system as claimed in claim 1, wherein the code that causes the one or more processors to convert the one or more power images and associated metadata to one or more transient event vectors comprises code that causes the one or more processors to create a transient event vector for each power image and associated metadata.

4. The power monitoring system as claimed in claim 3, wherein the one or more processors are further configured to execute code to cause the one or more processors to:
combine the transient event vectors for each power image related to the transient event by one of averaging or pooling the transient event vectors to create a combined transient event vector; and
using the combined transient event vector to search the vector database.

5. The power monitoring system as claimed in claim 1, wherein the code that causes the one or more processors to convert the one or more power images and associated metadata to one or more transient event vectors comprises code that causes the one or more processors to place each of the one or more power images received into an image sequence and consolidating the image sequence into one transient event vector.

6. The power monitoring system as claimed in claim 1, wherein the power controller resides at a central location and the one or more power vector analyzers are distributed across a power grid.

7. The power monitoring system as claimed in claim 1, wherein each of the one or more power vector analyzers are distributed across a power grid and each power vector analyzer contains the power controller, and the one or more power vector analyzers communicate with others of the one or more power vector analyzers to update the vector database at each power vector analyzer.

8. The power monitoring system as claimed in claim 1, wherein each power vector analyzer further comprises one or more processors configured to execute code to cause the one or more processors to define a limit mask for each phase of power being displayed on a display of the power vector analyzer.

9. The power monitoring system as claimed in claim 8, wherein the one or more processors are further configured to execute code that causes the one or more processors to:
receive a signal indicating that the power vector analyzer is to null quiescent power for each phase of power being displayed on the display of the power vector analyzer; and
display apparent power for each phase of power.

10. The power monitoring system as claimed in claim 9, wherein the one or more processors are further configured to:
determine that a transient event has occurred because power in one or more of phases exceeded a tracking mask limit for that phase;
subtract the quiescent power of each phase of power from a total event power; and
display an image of power for the transient event at a center of the display with the transient event being displayed as a deviation from the quiescent power, the image of the transient event becoming one of the one or more the power images.

11. The power monitoring system as claimed in claim 1, wherein the vector database resides in a centralized location and the one or more processors are further configured to execute code that causes the one or more processors to:
monitor power grid operations; and
provide one or more of artificial intelligence and machine learning services that include at least one of predictive measures, predictive maintenance, load sharing, peak power distribution and anomaly trend identification, based upon the monitoring.

12. A method of monitoring power in a grid, comprising:
receiving one or more power images with associated metadata for a transient event in at least one phase of three phases of power from one or more power vector analyzers;
converting the power images from the one or more power vector analyzers and the associated metadata to one or more transient event vectors; and
store the one or more transient event vectors in a vector database.

13. The method as claimed in claim 12, further comprising:
searching the vector database for vectors that match one of the one or more transient event vectors; and
when a match is found, use a classification from the match to classify the transient event.

14. The method as claimed in claim 12, wherein converting the one or more power images and associated metadata to one or more transient event vectors comprises creating a transient event vector for each power image and associated metadata.

15. The method as claimed in claim 14, wherein converting the one or more power images and associated metadata to one or more transient event vectors comprises:
combining the transient event vectors for each power image related to the transient event by one of averaging or pooling the transient event vectors to create a combined transient event vector; and
using the combined transient event vector to search the vector database.

16. The method as claimed in claim 12, wherein converting the one or more power images and associated metadata to one or more transient event vectors comprises placing each of the one or more power images received into an image sequence and consolidating the image sequence into one transient event vector.

17. The method as claimed in claim 12, further comprising:
receiving a signal at the one or more power vector analyzers indicating that the one or more power vector analyzers are to null quiescent power for each of phase of power being displayed on a user interface of one of the one or more the power vector analyzers; and
displaying apparent power for each phase of power.

18. The method as claimed in claim 17, further comprising:
determining that a transient event has occurred because power in one or more phases exceeded a tracking mask limit for that phase;
subtracting quiescent power of each phase from a total event power; and
displaying an image of power for the transient event at a center of the display with the transient event being displayed as a deviation from the quiescent power, the image of the transient event becoming one of the one or more power images.

19. The method as claimed in claim 12, further comprising:
monitoring power grid operations; and
providing one or more of artificial intelligence and machine learning services that include at least one of predictive measures, predictive maintenance, load sharing, peak power distribution and anomaly trend identification, based upon the monitoring.
